(19) United States
(12) Patent Application Publication
(10) Pub. No.: US 2026/0139339 A1
(43) Pub. Date: May 21, 2026

(54) Flat Steel Product for Producing a Steel Component by Hot Forming, Method for The Production Thereof and Method for Producing the Steel Component

(71) Applicant: ThyssenKrupp Steel Europe AG, Duisburg (DE)

(72) Inventors: Robin Dohr, Voerde (DE); Michael Stang, Kerken (DE); Maria Köyer, Dortmund (DE); Christian Altgassen, Dortmund (DE)

(21) Appl. No.: 19/121,863

(22) PCT Filed: Oct. 20, 2023
(86) PCT No.: PCT/EP2023/079226

§ 371 Date: Apr. 17, 2025

(30) Foreign Application Priority Data
Oct. 20, 2022 (DE) 10 2022 127 696.1

(51) Int. Cl. C21D 8/0278; C09D 5/10; C21D 9/46; C22C 38/04; C23C 16/02; C23C 16/26

(52) U.S. Cl. CPC C21D 8/0278; C09D 5/103; C21D 9/46; C22C 38/04; C23C 16/0272; C23C 16/26

(57) ABSTRACT

A flat steel product for producing a steel component by hot forming includes a steel substrate, which consists of a steel having 0.1-3 wt. % Mn and optionally up to 0.01 wt. % B, and an aluminum-based anticorrosion coating deposited on the steel substrate, and an absorption layer including carbon particles is arranged on the anticorrosion coating. A method is disclosed for producing a flat steel product, and to the use of carbon particles in an absorption layer on a flat steel product coated with an aluminum-based anticorrosion coating in order to reduce the reflectivity in the infrared region. A method is disclosed for producing a steel component from a flat steel product.

### CROSS-REFERENCE TO RELATED APPLICATIONS

This application is the United States national phase of International Patent Application No. PCT/EP2023/079226 filed Oct. 20, 2023, and claims priority to German Patent Application No. 10 2022 127 696.1 filed Oct. 20, 2022, the disclosures of which are hereby incorporated by reference in their entireties.

### BACKGROUND OF THE INVENTION

### Field of the Invention

The invention relates to a flat steel product for producing a steel component by hot forming, to a method for producing such a flat steel product, to a method for producing a steel component from such a flat steel product and to the use of carbon particles in an absorption layer on a flat steel product coated with an aluminum-based anticorrosion coating for reducing reflectivity in the infrared range.

The term “flat steel product” in the present case refers to all rolled products whose length is several times greater than their thickness. These include steel strips and sheets as well as blanks obtained therefrom.

### Description of Related Art

In hot forming, also referred to as thermoforming, press hardening or hot press hardening, flat steel products, such as steel blanks, which are separated from cold- or hot-rolled steel strip are heated to a deformation temperature that is usually above the austenitizing temperature (AC3) of the relevant steel and are placed in the tool of a forming press in the heated state. During the subsequent forming process, the sheet metal blank or the component formed therefrom undergoes rapid cooling due to being in contact with the cool tool. Cooling rates are adjusted in such a way that a hardened structure is created in the steel substrate. In the process, the structure is transformed into an at least partially martensitic structure. As a result of hot forming, a hardened steel component is obtained.

The flat steel product is typically heated in a preheated roller hearth furnace through which the flat steel product passes. In practice, this creates the problem that the radiant heat is reflected at the smooth and reflective surfaces of the metal anticorrosion coating applied to the flat steel product. This leads to a significant delay in the heating process, with the result that more time and energy is required for heating.

From the point of view of optimal energy use, it would therefore be desirable to transfer the thermal energy, which is usually introduced as thermal radiation, into the flat steel product during heating as efficiently as possible. A shorter heating time of the flat steel product to the deformation temperature would mean that the corresponding roller hearth furnaces could be shorter, which would have a positive effect on both the space required and the cost of purchasing them. In addition, the duration of the method could be reduced by shortening the heating time. The CO₂ emissions produced during the method could also be reduced. Overall, this would result in an optimized way of controlling the process.

Flat steel products with various anticorrosion coatings are known from WO 2012/120081 A2. To improve heating behavior, various cover layers are proposed which contain a metal compound from the group of oxide, nitride, sulfide, sulfate, carbide, carbonate, fluoride, hydrate, hydroxide or phosphate compounds. The disadvantage of these cover layers is that they have a negative effect on the product properties, such as scaling protection, tendency to corrode, weldability and/or paintability.

### SUMMARY OF THE INVENTION

Against this background, the object addressed by the invention was to provide a flat steel product that can be brought to the starting temperature required for hot forming within shorter heating times. Furthermore, a method allowing the production of such a flat steel product as well as a method for producing a steel component made from such a flat steel product should be provided.

This object is achieved by a flat steel product for producing a steel component by hot forming, comprising a steel substrate consisting of a steel having 0.1-3 wt. % Mn and optionally up to 0.01 wt. % B, and an aluminum-based anticorrosion coating deposited on the steel substrate, wherein an absorption layer comprising carbon particles is arranged on the anticorrosion coating.

Within the context of the invention, carbon particles are particles consisting of elemental carbon. Particles within the meaning of the invention consist of a solid and have a hydrodynamic diameter of 1 to 500 nm. A plurality of these primary particles can be joined together to form aggregates with a hydrodynamic diameter of 50 to 1000 nm. Typically, these aggregates are combined to form further agglomerates with diameters from 1 to 100 μm. The hydrodynamic diameter of the particles is determined using dynamic light scattering (DLS).

The carbon particles are preferably those selected from the group consisting of graphite, fullerenes, graphene, carbon nanotubes and mixtures thereof.

Carbon particles have the advantage that even when small amounts are used in the absorption layer, a significant degree of absorption in the infrared range is achieved, and thus a reduction in reflectivity in the infrared range. The infrared range in particular is the range of the radiation spectrum in which the interior of the furnace emits radiation, which substantially serves to heat the sheet metal blanks to the deformation temperature. The reduction in the degree of reflectivity of the flat steel product or the increase in the absorption in the infrared range by the absorption layer comprising carbon particles thus leads to faster heating of the flat steel product to the deformation temperature. In addition, the absorption layer comprising carbon particles is almost completely burned during hot forming at 920° C. such that the absorption layer does not adversely affect the properties, such as weldability, tendency to corrode, scaling protection and paintability, of the steel component obtained from the flat steel product after hot forming.

Within the context of this application, the infrared range is understood as the wave number range from 667-10000 cm⁻¹. This corresponds to the wavelength range of 1-15 μm.

In addition, an absorption layer with good adhesion that comprises carbon particles can be easily produced by immersing the flat steel product in an aqueous dispersion comprising carbon particles or spraying it with such a dispersion or coating it by means of coil coating or chemical or physical vapor deposition (CVD or PVD). During the subsequent drying process of the flat steel product, an absorption layer comprising carbon particles forms on the aluminum-containing surface of the anticorrosion coating and covers the highly reflective aluminum-based anticorrosion coating.

The absorption layer lies on top of the anticorrosion coating and directly adjoins it. In particular, the absorption layer is a cover layer which closes off the layer structure formed on the flat steel product according to the invention on each of its outer sides.

It has proven to be particularly practical if the absorption layer has a (dry) coating weight of 0.09 to 10 g/m², in particular 0.5 to 5 g/m², on each side of the flat steel product. Coating weights of less than 0.09 g/m² do not show sufficient reduction in the absorption rate, while at coating weights of more than 10 g/m², in particular more than 5 g/m², saturation of the effect occurs. Applying a higher coating weight is therefore possible but uneconomical.

In a preferred variant of the flat steel product according to the invention, the thickness of the absorption layer is 0.05 to 5 μm. The thickness is to be understood to mean the thickness on each side of the flat steel product. The two large, opposite surfaces of the flat steel product are referred to as the two sides of the flat steel product. The narrow surfaces are called edges. For flat steel products coated on both sides with an absorption layer on both sides, the thickness on each of the two sides is thus 0.05 to 5 μm. It has been shown that even such small thicknesses of the absorption layer lead to a significant reduction in the degree of reflectivity.

The reflectivity R in the infrared range is determined using a blackbody radiator as a reference for the purposes of this application. The blackbody has a temperature of T=920° C., which corresponds to an average furnace temperature. The spectral radiant power i_{λ}(T) of the blackbody radiator at the temperature T is therefore multiplied by the measured spectral reflectivity pa and integrated over the wavelength range. This integral is standardized to the spectral radiant power integrated over the same wavelength range. Therefore:

$$\overline{R} ( T ) = \frac{{\int }_{{λ}_{1}}^{{λ}_{2}} {ρ}_{λ} \cdot {i}_{λ} ( T ) d λ}{{\int }_{{λ}_{1}}^{{λ}_{2}} {i}_{λ} ( T ) d λ}$$

applies.

This results in i_{λ}(T) from Planck's law

$${i}_{λ} ( T ) = 2 π \frac{{hc}^{2}}{{λ}^{5}} \frac{1}{{e}^{\frac{hc}{{λ k}_{B} T}} - 1}$$

with the speed of light c, Planck's constant h and the Boltzmann constant k_{B}. The integration is carried out over the wavelength range corresponding to the wave numbers 667-10000 cm⁻¹, respectively, i.e., from λ₁=1 μm to λ₂=15 μm. The reflectivity R̅ used hereinafter is defined as R̅ (920° C.).

According to the invention, the absorption layer comprises carbon particles. The proportion of carbon particles in the dry absorption layer can be 10-99 wt. %, preferably 30-99 wt. %, particularly preferably 50-99 wt. %. The effect according to the invention occurs even with very small amounts of carbon particles in the absorption layer and increases as the amount of carbon particles increases. A particularly high degree of absorption in the infrared range, and thus a particularly advantageous reduction in reflectivity in the infrared range, is achieved when the proportion of carbon particles in the dry absorption layer is 60-99 wt. %, in particular 80-99 wt. %, preferably 90-99 wt. % and particularly preferably 95-99 wt. %.

The other configuration regarding the carbon particles in the absorption layer has already been described above.

According to a preferred embodiment of the flat steel product according to the invention, the absorption layer comprises at least one surfactant. The presence of the at least one surfactant leads to improved wettability of the absorption layer on the anticorrosion coating.

Suitable surfactants include anionic, cationic, zwitterionic and nonionic surfactants as well as mixtures thereof, for example.

According to a preferred embodiment of the flat steel product according to the invention, the at least one surfactant is selected from the group consisting of alkyl sulfates, alkyl sulfonates, alkyl phosphonates, alkoxylated fatty alcohols, alkoxylated fatty acids, alkoxylated fatty acid amines, alkoxylated alkylphenols, or alkyl polyglycosides.

It has proven to be particularly practical if the “alkyl” of the aforementioned alkyl sulfates, alkyl sulfonates, alkyl phosphonates, alkylphenols and/or alkyl polyglycosides has a chain length of 8 to 22 carbon atoms.

Preferably, alkoxylated fatty alcohols, fatty acids and/or fatty acid amines having an alkyl chain length of 6 to 22 carbon atoms are used.

The alkoxylated fatty alcohols, fatty acids, fatty acid amines and/or alkylphenols can be ethoxylated, propoxylated or butoxylated fatty alcohols, fatty acids, fatty acid amines and/or alkylphenols. The degree of ethoxylation, propoxylation or butoxylation can be from 1-18, preferably from 3-10.

The proportion of the at least one surfactant in the dry absorption layer is 0.01 to 5 wt. %, in particular from 0.5 to 2 wt. %. A minimum content of 0.01 wt. % has proven to be necessary to ensure the wettability of the aluminum-based anticorrosion coating. A proportion of more than 5 wt. % surfactant in the absorption layer does not lead to any further improvement in wettability and therefore does not make sense from an economic point of view.

In order to also improve the adhesion of the absorption layer to the aluminum-based anticorrosion coating in addition to the wettability of the sheet metal surface, the absorption layer can also contain at least one polymer in addition to the surfactant. An embodiment of the flat steel product according to the invention comprising an absorption layer which comprises at least one surfactant and at least one polymer is therefore particularly preferred.

Suitable polymers include polyalkylene glycols and mixtures thereof.

According to a preferred embodiment of the flat steel product according to the invention, the at least one polymer is selected from polyethylene glycols or polypropylene glycols. Good results could be achieved particularly with polyethylene glycols or polypropylene glycols, whose molecular weight is in the range of 400 to 5000 g/mol.

The proportion of the at least one polymer in the dry absorption layer can be 1 to 90 wt. %. A minimum content of 1 wt. % is required to obtain the above-mentioned advantageous improvement in adhesion. The addition of more than 90 wt. % has an adverse effect on reflectivity and drying of the coating.

The aluminum-based anticorrosion coating can be deposited on one or both sides of the flat steel product. “Aluminum-based anticorrosion coating,” as used herein, means that the anticorrosion coating consists of more than 50 wt. % aluminum.

Such an anticorrosion coating is preferably produced by hot-dip coating the flat steel product. The flat steel product is passed through a liquid melt which consists of up to 15 wt. % Si, preferably more than 1 wt. %, in particular more than 1.0 wt. % Si, optionally 2 to 4 wt. % Fe, optionally up to 5 wt. % alkali or alkaline earth metals, preferably up to 1.0 wt. % alkali or alkaline earth metals, and optionally up to 15 wt. % Zn, preferably up to 10 wt. % Zn and optionally further components, the total content of which is limited to a maximum of 2.0 wt. %, and the rest being aluminum.

In a preferred variant of the flat steel product according to the invention, the Si content in the melt is 1-3.5 wt. % or 7-12 wt. %, in particular 8-10 wt. %.

In a further preferred variant of the flat steel product according to the invention, the optional content of alkali or alkaline earth metals in the melt comprises 0.1-1.0 wt. % Mg, in particular 0.1-0.7 wt. % Mg, preferably 0.1-0.5 wt. %. Furthermore, the optional content of alkali or alkaline earth metals in the melt can in particular comprise at least 0.0015 wt. % Ca, preferably at least 0.01 wt. % Ca.

During hot-dip coating, iron diffuses from the steel substrate into the liquid coating so that the anticorrosion coating of the flat steel product has, in particular, an alloy layer and an aluminum base layer (Al base layer) upon solidification.

The alloy layer lies on top of the steel substrate and directly adjoins it. The alloy layer is essentially made up of aluminum and iron. The remaining elements from the steel substrate or the composition of the melt do not significantly accumulate in the alloy layer. The alloy layer preferably consists of 35-60 wt. % Fe, preferably α-iron, optional further components, the total content of which is limited to a maximum of 5.0 wt. %, preferably 2.0 wt. %, and the rest being aluminum, wherein the Al content preferably increases toward the surface. The optional further components include in particular the remaining components of the melt (i.e., silicon and optionally alkali or alkaline earth metals, in particular Mg or Ca) and the remaining components of the steel substrate in addition to iron.

The Al base layer lies on top of the alloy layer and directly adjoins it. Preferably, the composition of the Al base layer corresponds to the composition of the melt bath melt. This means that it consists of 1-15 wt. %, in particular 1.0-15 wt. %, Si, optionally 2-4 wt. % Fe, optionally up to 5 wt. % alkali or alkaline earth metals, preferably up to 1.0 wt. % alkali or alkaline earth metals, optionally up to 15 wt. % Zn and optionally further components, the total content of which is limited to a maximum of 2.0 wt. %, and the rest being aluminum.

In a preferred variant of the Al base layer, the optional content of alkali or alkaline earth metals comprises 0.1-1.0 wt. % Mg, in particular 0.1-0.7 wt. % Mg, preferably 0.1-0.5 wt. % Mg. Furthermore, the optional content of alkali or alkaline earth metals in the Al base layer can comprise in particular at least 0.0015 wt. % Ca, in particular at least 0.1 wt. % Ca.

In a further preferred variant of the anticorrosion coating, the Si content in the alloy layer is lower than the Si content in the Al base layer.

The anticorrosion coating preferably has a thickness of 5-60 μm, in particular 10-40 μm. The coating weight of the anticorrosion coating is in particular 30-360 g/m² for anticorrosion coatings on both sides or 15-180 g/m² in the one-sided variant. The preferred coating weight of the anticorrosion coating is 100-200 g/m² for coatings on both sides or 50-100 g/m² for coatings on one side. The coating weight of the anticorrosion coating is particularly preferably 120-180 g/m² for double-sided coatings or 60-90 g/m² for one-sided coatings.

The thickness of the alloy layer is preferably less than 20 μm, particularly preferably less than 16 μm, particularly preferably less than 12 μm, in particular less than 10 μm. The thickness of the Al base layer results from the difference between the thicknesses of the anticorrosion coating and the alloy layer. Preferably, the thickness of the Al base layer is at least 1 μm, even for thin anticorrosion coatings.

In a preferred variant of the flat steel product, the average reflectivity R in the infrared range is less than 0.55, in particular less than 0.50, preferably less than 0.45, in particular less than 0.40, preferably less than 0.35, particularly preferably less than 0.30, in particular less than 0.25, preferably less than 0.20, in particular less than 0.15. The smaller the degree of reflectivity in the infrared range, the higher the heating rate during the subsequent production process of a steel component.

The invention also relates to the use of carbon particles in an absorption layer on a flat steel product coated with an aluminum-based anticorrosion coating for reducing reflectivity in the infrared range. This use has the same advantages as those explained above with regard to the flat steel product. Furthermore, the invention also relates to the use of the above-mentioned specially developed absorption layers and in particular to the use of a mixture of carbon particles with at least one surfactant and/or polymer in an absorption layer on an anticorrosion coating with 0.1-1.0 wt. % Mg in the Al base layer.

The steel substrate is made of a steel containing 0.1-3 wt. % Mn and optionally up to 0.01 wt. % B. In particular, the structure of the steel can be converted into a martensitic or partially martensitic structure by hot forming. The structure of the steel substrate of the steel component is therefore preferably a martensitic or at least partially martensitic structure, since this has particularly high hardness.

Particularly preferably, the steel substrate is a steel which, in addition to iron and unavoidable impurities (in wt. %), consists of

$$C : 0.04 - 0.45 wt . \% ,$$

$$Si : 0.02 - 1.2 wt . \% ,$$

$$Mn : 0.5 - 2.6 wt . \% ,$$

$$Al : 0.02 - 1. wt . \% ,$$

$$P : \leq 0.05 wt . \% ,$$

$$S : \leq 0.02 wt . \% ,$$

$$N : \leq 0.02 wt . \% ,$$

$$Sn : \leq 0.03 wt . \%$$

$$As : \leq 0.01 wt . \%$$

$$Ca : \leq 0.005 wt . \%$$

and optionally one or more of the elements “Cr, B, Mo, Ni, Cu, Nb, Ti, V” in the following amounts

$$Cr : 0.08 - 1. wt . \% ,$$

$$B : 0.001 - 0.005 wt . \%$$

$$Mo : \leq 0.5 wt . \%$$

$$Ni : \leq 0.5 wt . \%$$

$$Cu : \leq 0.2 wt . \%$$

$$Nb : 0.02 - 0.08 wt . \% ,$$

$$Ti : 0.01 - 0.08 wt . \%$$

$$V : \leq 0.1 wt . \% .$$

The elements P, S, N, Sn, As, Ca are impurities that cannot be completely avoided during steel production. In addition to these elements, other elements may also be present in the steel as impurities. These other elements which may be present in the steel as impurities in addition to the elements P, S, N, Sn, As and Ca, are summarized as “unavoidable impurities.” Preferably, the total content of unavoidable impurities is a maximum of 0.2 wt. %, preferably a maximum of 0.1 wt. %.

The optional alloying elements Cr, B, Nb, Ti, for which a lower limit is specified, can also occur as unavoidable impurities in the steel substrate in amounts that are below the corresponding lower limit. In this case, they are also included in the unavoidable impurities, the total content of which is limited to a maximum of 0.2 wt. %, preferably a maximum of 0.1 wt. %. Preferably, the individual upper limits for each of the impurities of these elements are as follows:

$$Cr : \leq 0.05 wt . \% ,$$

$$B : \leq 0.0005 wt . \%$$

$$Nb : \leq 0.005 wt . \% ,$$

$$Ti : \leq 0.005 wt . \%$$

These preferred upper limits may be considered as alternatives or altogether. Preferred variants of the steel therefore meet one or more of these four conditions.

In a preferred embodiment, the C content in the steel is a maximum of 0.37 wt. % and/or at least 0.06 wt. %. In particularly preferred variants, the C content is in the range from 0.06-0.09 wt. % or in the range from 0.12-0.25 wt. % or in the range from 0.33-0.37 wt. %.

In a preferred embodiment, the Si content in the steel is a maximum of 1.00 wt. % and/or at least 0.06 wt. %.

In a preferred variant, the Mn content in the steel is a maximum of 2.4 wt. % and/or at least 0.75 wt. %. In particularly preferred embodiments, the Mn content is in the range from 0.75-0.85 wt. % or in the range from 1.0-1.6 wt. %.

In a preferred variant, the Al content in the steel is a maximum of 0.75 wt. %, in particular a maximum of 0.5 wt. %, preferably a maximum of 0.25 wt. %. Alternatively or additionally, the Al content is preferably at least 0.02%.

It has also been found that it can be helpful if the sum of the content of silicon and aluminum is limited. In a preferred variant, the sum of the content of Si and Al (usually referred to as Si+Al) is therefore a maximum of 1.5 wt. %, preferably a maximum of 1.2 wt. %. Additionally or alternatively, the sum of the content of Si and Al is at least 0.06 wt. %, preferably at least 0.08 wt. %.

The elements P, S and N are typical impurities that cannot be completely avoided during steel production. In preferred variants, the P content is a maximum of 0.03 wt. %. Irrespective of this, the S content is preferably a maximum of 0.012%. Additionally or supplementarily, the N content is preferably a maximum of 0.009 wt. %.

Optionally, the steel also contains chromium with a content of 0.08-1.0 wt. %. Preferably, the Cr content is a maximum of 0.75 wt. %, in particular a maximum of 0.5 wt. %.

In the case of optionally alloying chromium, the sum of the content of chromium and manganese is preferably limited. The sum is a maximum of 3.3 wt. %, in particular a maximum of 3.15 wt. %. Furthermore, the sum is at least 0.5 wt. %, preferably at least 0.75 wt. %.

Preferably, the steel optionally also contains boron with a content of 0.001-0.005 wt. %. In particular, the B content is a maximum of 0.004 wt. %.

Optionally, the steel may contain molybdenum in a content of no more than 0.5 wt. %, in particular no more than 0.1 wt. %.

Furthermore, the steel can optionally contain nickel with a content of no more than 0.5 wt. %, preferably no more than 0.15 wt. %.

Optionally, the steel may also contain copper with a content of no more than 0.2 wt. %, preferably no more than 0.15 wt. %.

In addition, the steel can optionally contain one or more of the microalloying elements Nb, Ti and V. The optional Nb content is at least 0.02 wt. % and a maximum of 0.08 wt. %, preferably a maximum of 0.04 wt. %. The optional Ti content is at least 0.01 wt. % and a maximum of 0.08 wt. %, preferably a maximum of 0.04 wt. %. The optional V content is a maximum of 0.1 wt. %, preferably a maximum of 0.05 wt. %.

In the case of optionally alloying a plurality of the elements Nb, Ti and V, the sum of the content of Nb, Ti and V is preferably limited. The sum does not exceed 0.1 wt. %, in particular does not exceed 0.068 wt. %. Furthermore, the sum is preferably at least 0.015 wt. %.

The above explanations regarding preferred steel substrates naturally also apply to the steel substrates in the manufacturing method according to the invention described below.

The invention further relates to a method for producing a flat steel product according to the invention, comprising at least the following work steps:
a) providing a flat steel product comprising a steel substrate consisting of a steel having 0.1-3 wt. % Mn and optionally up to 0.01 wt. % B, and an aluminum-based anticorrosion coating deposited on the steel substrate,
b) applying an absorption layer comprising carbon particles to the flat steel product, in particular by
(i) immersing the flat steel product in an aqueous dispersion comprising carbon particles, or
(ii) spraying the flat steel product with an aqueous dispersion comprising carbon particles, or
(iii) coating the flat steel product with an aqueous dispersion comprising carbon particles by coil coating or by chemical or physical vapor deposition.

Through this treatment, the aqueous dispersion comprising carbon particles is evenly distributed over the entire surface so that a homogeneous absorption layer that covers the entire surface and comprises carbon particles is formed. Alternatively, the homogeneous absorption layer covering the entire surface is formed by chemical or physical vapor deposition.

In a preferred embodiment of the method according to the invention, the pH of the aqueous dispersion is at most 14, in particular at most 13, preferably at most 12, particularly preferably at most 10. This ensures that the aluminum-based anticorrosion coating has good wettability and thus that the aqueous dispersion and the carbon particles it contains are distributed particularly evenly. It has proven to be particularly practical if the pH value of the aqueous dispersion is at least 8 and at most 12, in particular at least 8 and at most 10.

In particular, the aqueous dispersion contains 1-70 wt. %, in particular 2-50 wt. % carbon particles, based on the total weight of the aqueous dispersion.

In a preferred development of the method according to the invention, the aqueous dispersion additionally contains at least one surfactant. This can improve the stability of the dispersion. Furthermore, the presence of the at least one surfactant in the aqueous dispersion also has an advantageous effect on the wettability of the aluminum-based anticorrosion coating. By additionally adding at least one polymer to the aqueous dispersion, improved adhesion of the absorption layer to the anticorrosion coating can be obtained.

The statements made above in connection with the flat steel product according to the invention apply, mutatis mutandis, to each design of the surfactant and the polymer.

The proportion of the at least one surfactant in the aqueous dispersion is 0 to 5 wt. %, based on the total weight of the aqueous dispersion. A minimum content of 0.1 wt. % is required to obtain the advantageous effects mentioned. The addition of more than 5 wt. % does not make sense for economic reasons, since an increase in the advantageous effects can no longer be observed.

The proportion of the at least one polymer in the aqueous dispersion is 0 to 50 wt. %, based on the total weight of the aqueous dispersion. A minimum content of 1 wt. % is required to obtain the advantageous effects mentioned. The addition of more than 50 wt. % has a detrimental effect on reflectivity and drying of the absorption layer obtained from the aqueous dispersion.

It goes without saying that the proportion of carbon particles and the proportion of the at least one surfactant that may be present and the at least one polymer that may also be present in the aqueous dispersion can be varied depending on the type of application in order to set a desired proportion of the carbon particles and the at least one surfactant that may be present and the at least one polymer that may also be present in the dry absorption layer. For example, it may be practical to immerse the flat steel product in an aqueous dispersion with a significantly lower proportion of carbon particles, while a higher proportion of carbon particles in the aqueous dispersion is required when coating it in order to obtain the same desired proportion of carbon particles in the dry absorption layer.

In case of immersing according to (i) of step b) of the method according to the invention, the immersion process is preferably carried out for an immersion time of 0.5 to 30 s, preferably 1 to 5 s. A longer immersion time has the advantage of ensuring that the flat steel product is wetted. However, for industrial production, a shorter immersion time is advantageous in order to make the manufacturing process efficient. The times mentioned have proven to be a good compromise in this respect.

In a preferred development of the method, the flat steel product has a temperature of 40° C. to 100° C., preferably 50° C. to 80° C., when the aqueous dispersion is applied, in particular by immersing or spraying or coating said flat steel product by coil coating or when coating by chemical vapor deposition. When applying the aqueous dispersion, a higher temperature accelerates the drying process of the absorption layer and thus the formation of layers. However, if the temperature is too high, the aqueous dispersion evaporates too quickly, and therefore the layers are not reliably formed. For chemical vapor deposition, the temperature ranges mentioned are advantageous in order to accelerate the reactions at the surface.

In the case of coating according to (iii) of step b) of the method according to the invention by means of chemical vapor deposition (CVD) or physical vapor deposition (PVD), coating can be carried out in such a way that, for example, the combustion of gas, for example methane, propane, butane or acetylene, takes place on a hot flat steel product surface which is formed by the aluminum-based anticorrosion coating, or coating takes place via liquid-feed flame spray pyrolysis, in which a carbon-containing precursor, for example methane, propane, butane or acetylene, is incompletely burned and the resulting carbon particles adhere to the surface of the flat steel product, or coating takes place from a carbon target, for example consisting of graphite or amorphous carbon, by sputtering PVD in a vacuum.

In an alternative preferred variant of the method according to the invention, the flat steel product is subjected to an activation treatment before step b), wherein an adhesion promoter is applied to the aluminum-based anticorrosion coating. The same polymers that have already been described in detail above with regard to the flat steel product according to the invention can serve as adhesion promoters. The embodiments of these polymers described therein are analogously applicable to the method according to the invention. By applying an adhesion-promoting layer to the anticorrosion coating, particularly good adhesion of the carbon particles in the absorption layer can be ensured even if they are applied via CVD or PVD.

The invention further relates to a method for producing a steel component, comprising the following work steps:
a) providing a sheet metal blank from a flat steel product according to the invention;
b) heating the sheet metal blank in such a way that the AC3 temperature of the blank is at least partially exceeded and the temperature T_{place} of the blank, when placed in a forming tool intended for hot press forming (work step c)), at least partially has a temperature above Ms+100° C., wherein Ms denotes the martensite start temperature, wherein the average heating rate is greater than 15 Kmm/s;
c) placing the heated sheet metal blank in a forming tool, wherein the transfer time t_{Trans} required for removing the blank from the heating device and placing it in the tool is not more than 20 s, preferably not more than 15 s;
d) hot press forming the sheet metal blank to form the steel component, wherein, during hot press forming, the blank is cooled for a period of time t_{TOOL} of more than 1 s with a cooling rate r_{TOOL} of at least partially more than 30 K/s to the target temperature T Target and optionally held at this temperature;
e) removing the steel component cooled to the target temperature T Target from the tool.

In the method according to the invention, a blank consisting of a flat steel product according to the invention as described above is thus provided (work step a)). This blank is heated with an average heating rate greater than 15 Kmm/s in such a way that the AC3 temperature of the blank is at least partially exceeded and the temperature T_{place} of the blank, when placed in a forming tool intended for hot press forming (work step c)), is at least partially at a temperature above Ms+100° C.

The average heating rate is to be understood as the product of the average heating rate from 30° C. to 700° C. and the sheet metal thickness. The average heating rate is more than 15 Kmm/s, in particular more than 20 Kmm/s, preferably more than 25 Kmm/s, in particular more than 30 Kmm/s. The heating process in step a) preferably takes place in a furnace, in particular a roller hearth furnace. Therefore, heat radiation dominates over heat conduction when heating the sheet metal blanks. The absorption layer according to the invention increases the proportion of absorbed thermal radiation, resulting in advantageous high average heating rates.

For the purposes of this application, partially exceeding a temperature (here AC3 or Ms+100° C.) means that at least 30%, in particular at least 60%, of the volume of the blank exceeds a corresponding temperature. When placed in the forming tool, at least 30% of the blank thus has an austenitic structure, i.e., the transformation from the ferritic to the austenitic structure need not have been completed when the blank is placed in the forming tool. Instead, up to 70% of the volume of the blank, when placed in the forming tool, can consist of other structural components, such as tempered bainite, tempered martensite and/or non- or partially recrystallized ferrite. For this purpose, certain regions of the blank can be kept at a lower temperature level than others during heating. For this purpose, the heat supply can be targeted directed only to certain portions of the blank or the parts that are not to be heated as much can be shielded from the heat supply. In the part of the blank material whose temperature remains lower, no or only significantly less martensite is formed during the forming process in the tool, so that the structure in this part is significantly softer than in each of the other parts in which a martensitic structure is present. In this way, a softer region can be specifically set in each of the formed steel components, for example by providing a degree of toughness optimal for the relevant intended use, while the other regions of the steel component have maximized strength.

Maximum strength properties of the resulting steel component can be achieved by ensuring that the temperature reached at least partially in the sheet metal blank is between AC3 and 1000° C., preferably between 850° C. and 950° C.

The minimum temperature AC3 to be exceeded is determined according to the formula given by HOUGARDY, H.P. in Werkstoffkunde Stahl (‘Materials Science: Steel’), volume 1: Grundlagen (‘Basics’), Verlag Stahleisen GmbH, Düsseldorf, 1984, p. 229:

$$AC 3 = ( 902 - {225}^{*} \% C + {19}^{*} \% Si - {11}^{*} \% Mn - {5}^{*} \% Cr + {13}^{*} \% Mo - {20}^{*} \% Ni + {55}^{*} \% V ) ° C .$$

where % C=corresponding C content, % Si=corresponding Si content, % Mn=corresponding Mn content, % Cr=corresponding Cr content, % Mo=corresponding Mo content, % Ni=corresponding Ni content and % V=corresponding V content of the steel from which the blank is made.

An optimally uniform distribution of properties can be achieved by completely heating the blank in work step b).

In a preferred variant, heating takes place in a furnace with a furnace temperature T_{Furnace} of at least 850° C., preferably at least 880° C., particularly preferably at least 900° C., in particular at least 920° C., and at most 1000° C., preferably at most 950° C., particularly preferably at most 930° C.

Preferably, the dew point in the furnace is at least −20° C., preferably at least −15° C., in particular at least −5° C., preferably at least 0° C., particularly preferably at least +5° C. and at most +25° C., preferably at most +20° C., in particular at most +15° C.

In a special variant of the method according to the invention, the heating process in step b) takes place in stages in regions of different temperatures. In particular, heating takes place in a roller hearth furnace with different heating zones. In this case, heating takes place in a first heating zone at a temperature (so-called furnace inlet temperature) of at least 650° C., preferably at least 680° C., in particular at least 720° C. The maximum temperature in the first heating zone is preferably 900° C., in particular at most 850° C. More preferably, the maximum temperature of all of the heating zones in the furnace is at most 1200° C., in particular at most 1000° C., preferably at most 950° C., particularly preferably at most 930° C.

The total time in the furnace t_{Furnace}, which is made up of a heating time and a holding time, is preferably at least 1 minute, in particular at least 2 minutes, preferably at least 3 minutes, in both variants (constant furnace temperature, heating in stages). Furthermore, the total time in the furnace for both variants is preferably at most 12 minutes, in particular at most 10 minutes, preferably at most 8 minutes, in particular at most 6 minutes. Longer total times in the furnace have the advantage that uniform austenitization of the sheet metal blank is ensured. On the other hand, holding above AC3 for too long leads to grain coarsening, which has a negative effect on the mechanical properties.

The blank heated in this way is removed from the corresponding heating device and transported to the forming tool quickly enough that its temperature upon arrival in the tool is at least partially above Ms+100° C., preferably above 600° C., in particular above 650° C., particularly preferably above 700° C. Here, Ms denotes the martensite start temperature. In a particularly preferred variant, the temperature is at least partially above the AC1 temperature. In all of these variants, the maximum temperature is in particular 900° C. These temperature ranges altogether ensure that the material is easy to form.

In work step c), the transfer of the austenitized blank from the heating device used each time to the forming tool is preferably completed within a maximum of 20 s, in particular within a maximum of 15 s. Such rapid transport is necessary to avoid excessive cooling before deformation.

When placing the blank in the tool, the tool typically has a temperature between room temperature (RT) and 200° C., preferably between 20° C. and 180° C., in particular between 50° C. and 150° C. Optionally, in a particular embodiment, at least regions of the tool can be brought to a temperature T_{TOOL} of at least 200° C., in particular at least 300° C., in order to only partially harden the steel component. Furthermore, the tool preferably has a temperature T_{TOOL} of at most 600° C., in particular at most 550° C. It is only necessary to ensure that the tool temperature T_{TOOL} is below the desired target temperature T Target. The residence time in the tool T_{TOOL} is preferably at least 2 s, in particular at least 3 s, particularly preferably at least 5 s. The maximum residence time in the tool is preferably 25 s, in particular 20 s.

The target temperature T_{Target} of the steel component is at least partially below 400° C., preferably below 300° C., in particular below 250° C., preferably below 200° C., particularly preferably below 180° C., in particular below 150° C. Alternatively, the target temperature T_{Target} of the steel component is particularly preferably below Ms−50° C., wherein Ms denotes the martensite start temperature. Furthermore, the target temperature of the steel component is preferably at least 20° C., particularly preferably at least 50° C.

The martensite start temperature of a steel within the scope of the specifications according to the invention can be calculated according to the formula:

$$Ms [ ° C . ] = ( 490.85 - 302.6 \% C - 30.6 \% Mn - 16.6 \% Ni - 8.9 \% Cr + 2.4 \% Mo -- 11.3 \% Cu + 8.58 \% Co + 7.4 \% W - 14.5 \% Si ) [ ° C . / wt . \% ]$$

wherein, again % C denotes the C content, % Mn denotes the Mn content, % Mo denotes the Mo content, % Cr denotes the Cr content, % Ni denotes the Ni content, % Cu denotes the Cu content, % Co denotes the Co content, % W denotes the W content and % Si denotes the Si content of the particular steel in wt. %.

The AC1 temperature and the AC3 temperature of a steel within the scope of the specifications according to the invention can be calculated according to the formulas:

$$AC 1 [ ° C . ] = ( 739 - {22}^{*} \% C - {7}^{*} \% Mn + {2}^{*} \% S i + {14}^{*} \% Cr + {13}^{*} \% Mo - {13}^{*} \% Ni + {20}^{*} \% V ) [ ° C . / wt . \% ]$$

$$AC 3 [ ° C . ] = ( 902 - {225}^{*} \% C + {19}^{*} \% Si - {11}^{*} \% Mn - {5}^{*} \% Cr + {13}^{*} \% Mo - {20}^{*} \% Ni + {55}^{*} \% V ) [ ° C . / wt . \% ]$$

wherein, again % C denotes the C content, % Si denotes the Si content, % Mn denotes the Mn content, % Cr denotes the Cr content, % Mo denotes the Mo content, % Ni denotes the Ni content and +% V denotes the vanadium content in the particular steel (Brandis H 1975 TEW-Techn. Ber. 1 8-10).

In the tool, the blank is therefore not only formed into the steel component, but is also quenched to the target temperature at the same time. The cooling rate in the tool r_{TOOL} to the target temperature is in particular at least 20 K/s, preferably at least 30 K/s, in particular at least 50 K/s, particularly preferably at least 100 K/s.

After removing the steel component in step e), the steel component is cooled to a cooling temperature T_{COOL} of less than 50° C. within a cooling period t_{COOL} from 0.5 to 600 s. This is usually done by air cooling.

The invention will be explained in more detail below on the basis of embodiments.

### BRIEF DESCRIPTION OF THE DRAWINGS

In the drawings:

FIG. 1 shows reflectivity as a function of wavelength for Comparative Example V and for Example 7 according to the invention;

FIG. 2 shows a heating diagram for Comparative Example V and Example 7 according to the invention;

FIG. 3 shows reflectivity as a function of the coating weight of the absorption layer;

FIG. 4 shows heating rate as a function of the coating weight of the absorption layer.

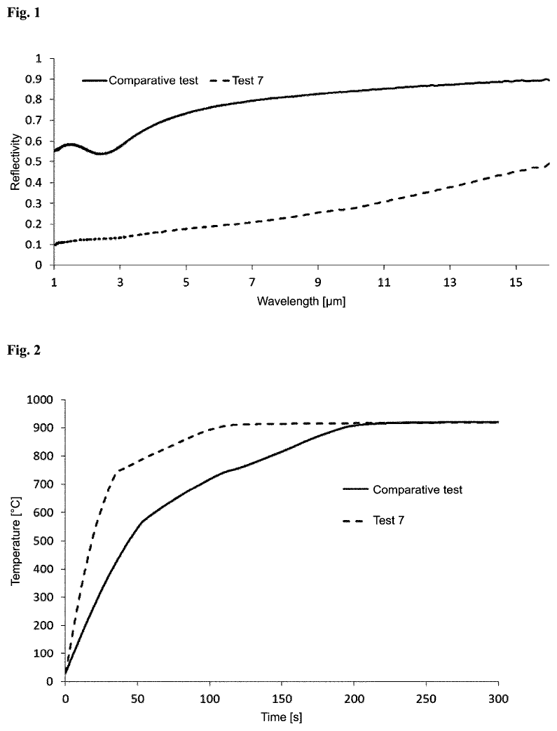

### DESCRIPTION OF THE INVENTION

To demonstrate the effect of the invention, Examples 1 to 7 according to the invention and Comparative Example V were carried out. For this purpose, steel blanks measuring 100×200 mm with a thickness of 1.5 mm and a steel composition according to Table 1 were coated with an aluminum-based anticorrosion coating by hot-dip coating.

The melt analysis of the anticorrosion coating is given in Table 2. The resulting anticorrosion coating had an Al base layer whose composition corresponds to the melt analysis. The thickness of the anticorrosion coating on one side was 25 μm.

The steel blanks thus provided were treated with an aqueous dispersion comprising carbon particles in order to produce an absorption layer on the anticorrosion coating (Examples 1 to 7 according to the invention). The particular composition of the aqueous dispersion can be found in Table 3.

Table 3 also provides the details of the treatment method. These are the application method, the pH value of the aqueous dispersion, the immersion time and the temperature of the steel blanks during treatment. The resulting properties, such as the coating weight of the absorption layer and the layer thickness of the absorption layer after drying, the average reflectivity in the infrared range and the heating rate, are also listed in Table 3.

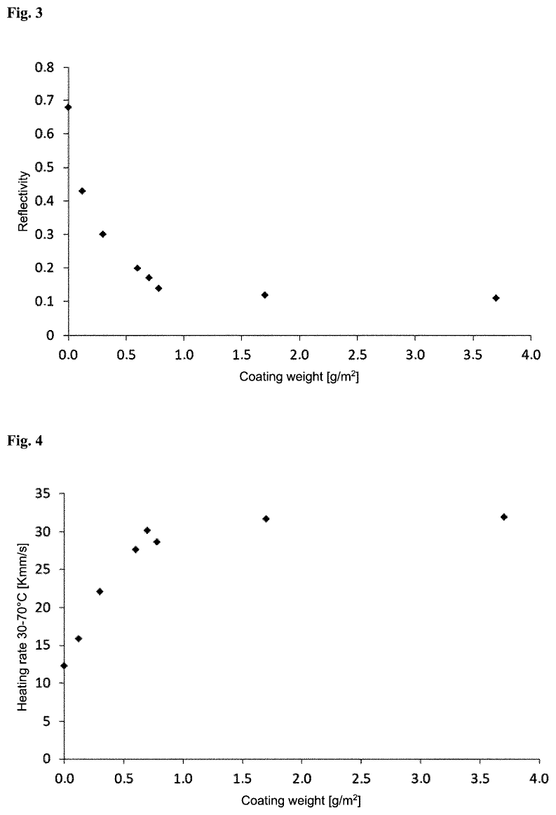

It can be seen from Table 3 that Examples 1 to 7 according to the invention have significantly lower average degrees of reflectivity in the infrared range compared to Comparative Example V (see also FIG. 3). Furthermore, the heating rate for Examples 1 to 7 according to the invention is significantly higher than for Comparative Example V (see also FIG. 4). When looking at the use of an aqueous dispersion with the same proportion of carbon particles, the average reflectivity decreases with increasing coating weight or increasing layer thickness of the dry absorption layer while the heating rate increases accordingly (see comparison of Examples 3 to 7 according to the invention). A comparison of Examples 6 and 7 according to the invention shows that from a certain coating weight or from a certain layer thickness of the absorption layer, saturation of the effect according to the invention occurs (see also FIGS. 3 and 4).

The steel blanks produced in this way were then processed into a steel component by means of hot forming. For this purpose, the blanks were heated in a roller hearth furnace from room temperature with an average heating rate r_{Furnace} (between 30° C. and 700° C.) and a furnace temperature of 920° C. The average heating rate is specified in Table 3.

The blanks were then further processed in a conventional manner. For this purpose, the blanks were removed from the roller hearth furnace and placed in a forming tool. When removed from the furnace, the blanks had reached the furnace temperature. The transfer time, which is made up of the removal from the heating device, transport to the tool and placement in the tool, was approximately 10 s. The temperature of the blanks when placed in the forming tool was, in all cases, above the relevant AC1 temperature and thus also above Ms+100° C.

The blanks were formed into the relevant steel components in the forming tool brought to room temperature, wherein the steel components were cooled in the tool at a cooling rate of approx. 50 K/s for approx. 15 s. Finally, the samples were removed from the tool and cooled to room temperature. Cooling was carried out in still air at a cooling rate of 7 K/s.

TABLE 1

| Steel | C | Si | Mn | Al | Cr | Nb | Ti | B | P | S | N | Sn | As | Cu | Mo | Ca | Ni |
|---|---|---|---|---|---|---|---|---|---|---|---|---|---|---|---|---|---|
| A | 0.235 | 0.3 | 1.3 | 0.05 | 0.28 | 0.003 | 0.040 | 0.0035 | 0.02 | 0.003 | 0.007 | 0.03 | 0.01 | 0.03 | 0.03 | 0.005 | 0.025 |

Remainder: iron and unavoidable impurities. Values are each in wt. %.

TABLE 2
Melt analysis

| Si | Fe | Mg | Other | Al |
|---|---|---|---|---|
| 9.5 | 3 | 0.3 | <1% | Remainder |

Melt analysis values are each in wt. %.

TABLE 3

| | | | | Proportion | | | | | Temper- | | Heating | |
|---|---|---|---|---|---|---|---|---|---|---|---|---|
| | | | Proportion | of carbon | Pro- | Pro- | | | ature | | rate | |
| | | | of carbon | particles in | portion of | portion of | | Immer- | of the | | between | |
| | Layer | Coating | particles in | dry absorp- | surfactant | polymer in | Appli- | sion | flat steel | | 30 and | Average |
| | thickness | weight | dispersion | tion layer | in disper- | dispersion | cation | time | product | pH | 700° C. | reflectivity |
| Test | (μm) | [g/m²] | [wt. %] | [wt. %] | sion [wt. %] | [wt. %] | method | [s] | [° C.] | value | [Kmm/s] | R̅ |
| V | — | — | — | — | — | — | — | — | — | — | 12.3 | 0.68 |
| 1 | 0.33 | 0.6 | 4 | 99.3 | 0.03 | — | Immersion | 2 | 25 | 8 | 27.6 | 0.2 |
| 2 | 0.43 | 0.78 | 4 | 99.3 | 0.03 | — | Immersion | 5 | 25 | 8 | 28.65 | 0.14 |
| 3 | 0.067 | 0.12 | 20 | 92.4 | 0.15 | 1.5 | Coil | <2 | 30 | 9 | 15.9 | 0.43 |
| | | | | | | | coating | | | | | |
| 4 | 0.17 | 0.3 | 20 | 92.4 | 0.15 | 1.5 | Coil | <2 | 30 | 9 | 22.14 | 0.3 |
| | | | | | | | coating | | | | | |
| 5 | 0.39 | 0.7 | 20 | 92.4 | 0.15 | 1.5 | Coil | <2 | 30 | 9 | 30.15 | 0.17 |
| | | | | | | | coating | | | | | |
| 6 | 0.94 | 1.7 | 20 | 92.4 | 0.15 | 1.5 | Coil | <2 | 30 | 9 | 31.65 | 0.12 |
| | | | | | | | coating | | | | | |
| 7 | 2.06 | 3.7 | 20 | 92.4 | 0.15 | 1.5 | Coil | <2 | 30 | 9 | 31.95 | 0.11 |
| | | | | | | | coating | | | | | |

1. A flat steel product for producing a steel component by hot forming, comprising a steel substrate consisting of a steel having 0.1-3 wt. % Mn and optionally up to 0.01 wt. % B, and an aluminum-based anticorrosion coating deposited on the steel substrate, wherein an absorption layer is arranged on the anticorrosion coating, and wherein the absorption layer comprises carbon particles.

2. The flat steel product according to claim 1, wherein the carbon particles are selected from the group consisting of graphite, fullerenes, graphene, carbon nanotubes and mixtures thereof.

3. The flat steel product according to any one of claim 1, wherein the absorption layer is 0.05 to 5 μm thick.

4. The flat steel product according to any one of claim 1, wherein the aluminum-based anticorrosion coating consists of 1-15 wt. % Si, optionally 2-4 wt. % Fe, optionally up to 5 wt. % alkali or alkaline earth metals, optionally up to 15 wt. % Zn and optionally further components, the total contents of which are limited to a maximum of 2.0 wt. %, and the rest being aluminum.

5. The flat steel product according to claim 4, wherein the aluminum-based anticorrosion coating contains up to 1.0 wt. % alkali or alkaline earth metals and comprises 0.1-1.0 wt. % Mg.

6. The flat steel product according to claim 1, wherein the average reflectivity in the infrared range is less than 0.55.

7. Use of carbon particles in an absorption layer on a flat steel product according to claim 1, the flat steel product coated with an aluminum-based anticorrosion coating for reducing reflectivity in the infrared range.

8. A method for producing a flat steel product according to claim 1, comprising the following work steps:
a) providing a flat steel product comprising a steel substrate consisting of a steel having 0.1-3 wt. % Mn and optionally up to 0.01 wt. % B, and an aluminum-based anticorrosion coating deposited on the steel substrate,
b) applying an absorption layer comprising carbon particles to the flat steel product by:
(i) immersing the flat steel product in an aqueous dispersion comprising carbon particles, or
(ii) spraying the flat steel product with an aqueous dispersion comprising carbon particles, or
(iii) coating the flat steel product with an aqueous dispersion comprising carbon particles by coil coating or by chemical or physical vapor deposition.

9. The method according to claim 8, wherein the pH of the aqueous dispersion is at least 8 and at most 12.

10. The method according to any one of claim 8, wherein the flat steel product is immersed in an aqueous dispersion comprising carbon particles for an immersion time of 0.5 to 30 s.

11. The method according to claim 8, wherein the flat steel product has a temperature of 40° C. to 100° C. when immersed in, sprayed or coated with the aqueous dispersion comprising carbon particles or when coated by chemical vapor deposition.

12. The method according to claim 8, wherein the aqueous dispersion further contains at least one surfactant, and additionally contains at least one polymer.

13. The method according to claim 12, wherein the at least one surfactant is selected from the group consisting of alkyl sulfates, alkyl sulfonates, alkyl phosphonates, alkoxylated fatty alcohols, alkoxylated fatty acids, alkoxylated fatty acid amines, alkoxylated alkylphenols, or alkyl polyglycosides, and the additionally contained at least one polymer is selected from polyethylene glycols or polypropylene glycols.

14. The method according to claim 8, wherein the aqueous dispersion has a solids content of 1 to 70 wt.

15. A method for producing a steel component, comprising the following work steps:
a) providing a sheet metal blank from a flat steel product according to claim 1;
b) heating the sheet metal blank in such a way that the AC3 temperature of the blank is at least partially exceeded and the temperature T_{place} of the blank, when placed in a forming tool intended for hot press forming (work step c), at least partially has a temperature above Ms+100° C., where Ms denotes the martensite start temperature, wherein the average heating rate is greater than 15 Kmm/s;
c) placing the heated sheet metal blank in a forming tool, wherein the transfer time t_{Trans} required for removing the blank from the heating device and placing it in the tool is not more than 20 s;
d) hot press forming the sheet metal blank to form the steel component, whereby the blank is hot press formed for a period of time t_{TOOL} of more than 1 s with a cooling rate r of at least partially more than 30 K/s cooled to the target temperature T_{Target} and optionally kept there;
e) removing the steel component cooled to the target temperature T_{Target} from the tool.

16. The flat steel product according to claim 1, wherein the average reflectivity in the infrared range is less than 0.45.

17. The flat steel product according to claim 1, wherein the average reflectivity in the infrared range is less than 0.25.

18. The method according to claim 9, wherein the pH of the aqueous dispersion is at least 8 and at most 10.

19. The method according to any one of claim 10, wherein the flat steel product is immersed in the aqueous dispersion comprising carbon particles for an immersion time of 1 to 5 s.

20. The method according to claim 11, wherein the flat steel product has a temperature of 50° C. to 80° C. when immersed in, sprayed or coated with the aqueous dispersion comprising carbon particles or when coated by chemical vapor deposition.

21. The method according to claim 14, wherein the aqueous dispersion has a solids content of up to 50 wt. %.

22. The method according to claim 15, wherein the transfer time t_{Trans} required for removing the blank from the heating device and placing it in the tool is not more than 15 s.
